(19) United States
(12) Patent Application Publication
(10) Pub. No.: US 2006/0099802 A1
(43) Pub. Date: May 11, 2006

(54) Diffusion barrier for damascene structures

(76) Inventors: Jing-Cheng Lin, HsinChu (TW); Shau-Lin Shue, Hsinchu (TW)

Correspondence Address: SLATER & MATSIL, L.L.P., 17950 PRESTON ROAD, SUITE 1000, DALLAS, TX, 75252, US

(21) Appl. No.: 10/985,149

(22) Filed: Nov. 10, 2004

(51) Int. Cl. H01L 21/4763

(52) U.S. Cl. 438/637

(57) ABSTRACT

A semiconductor structure having a via formed in a dielectric layer is provided. The exposed pores of the dielectric material along the sidewalls of the via are partially or completely sealed. Thereafter, one or more barrier layers may be formed and the via may be filled with a conductive material. The barrier layers formed over the sealing layer exhibits a more continuous barrier layer. The pores may be partially or completely sealed by performing, for example, a plasma process in an argon environment.

### TECHNICAL FIELD

The present invention relates generally to semiconductors and, more particularly, to a semiconductor structure with a barrier layer in a damascene opening and a method for forming such a semiconductor structure in an integrated circuit.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

One such challenge is the fabrication of interconnect structures. CMOS devices typically include semiconductor structures, such as transistors, capacitors, resistors, and the like, formed on a substrate. One or more conductive layers formed of a metal or metal alloy separated by layers of a dielectric material are formed over the semiconductor structures to interconnect the semiconductor structures and to provide external contacts to the semiconductor structures. Openings (e.g., contacts and vias in conventional metal interconnect structures, trenches and vias in damascene structures, or the like) are formed in the dielectric layers to provide an electrical connection between metal layers and/or a metal layer and a semiconductor structure.

Generally, one or more adhesion/barrier layers are formed in the openings to prevent electron diffusion from the conductive material, e.g., copper, aluminum, or the like, into the surrounding dielectric material and to enhance the adhesive properties of the conductive material to the dielectric material. For example, it is common to utilize a first barrier layer formed of tungsten, titanium or tantalum, which provides good adhesive qualities to the dielectric layer. A second barrier layer is commonly formed of tungsten nitride, titanium nitride or tantalum nitride, which provides good adhesion qualities to the first barrier layer and a filler material, such as tungsten, aluminum or copper that may be used to fill the openings, such as contact, trench or via.

However, the dielectric materials in which the openings are formed typically comprise a porous material, particularly with low-K dielectric materials having a dielectric constant less than about 2.75. The sidewall of the openings may be damaged during an etching and/or ashing process while forming the openings. The damaged sidewalls of the openings in the porous low-K dielectric layer may become more porous and rougher. As a result, a barrier layer formed over the sidewalls of the openings may be non-uniform, thereby allowing conductive material to diffuse into the porous low-K materials. In these situations, the non-uniform barrier layer may not provide an adequate diffusion barrier. This diffusion may result in failures and other reliability problems, particularly as design sizes decrease. Therefore, there is a need for a barrier layer that prevents or reduces diffusion.

### SUMMARY OF THE INVENTION

These and other problems are generally solved or circumvented, and technical advantages are generally achieved, by preferred embodiments of the present invention which provides a semiconductor structure with a barrier layer in a damascene opening.

In accordance with an embodiment of the present invention, a semiconductor structure is provided. The semiconductor structure comprises an opening defined through a porous low-K dielectric layer formed on a substrate. A protecting layer is formed on the dielectric layer along the sidewalls of the opening to protect the porous low-K dielectric layer along the sidewalls of the opening. The protecting layer preferably comprises more carbon concentration than the porous low-K dielectric layer and may comprise a nitrogen-containing, an oxygen-containing, a silicon-containing, a carbon-containing material, or the like. A barrier layer and a conductive material may be used to fill the opening.

In accordance with another embodiment of the present invention, a semiconductor structure is provided. The semiconductor structure comprises an opening defined through a porous low-K dielectric layer formed on a substrate. The sidewalls of the openings in the dielectric layer may comprise a carbonated, nitrogen or oxidized portion along the sidewall of the opening to protect the porous low-K dielectric layer on the sidewall of the opening. A barrier layer and a conductive material may be used to fill the opening.

In accordance with yet another embodiment of the present invention, a semiconductor structure is provided. A porous low-K dielectric layer is formed on a substrate, and an opening is formed through the porous low-K dielectric layer. The pores of the dielectric layer along the sidewalls of the opening are at least partially sealed. One or more barrier layers are formed along the sidewalls of the opening, and a conductive material may be used to fill the opening.

In accordance with yet another embodiment of the present invention, a method for fabricating a semiconductor structure with a pore-sealing process is provided. The method includes providing a substrate with a porous low-K dielectric layer formed thereon; forming an opening through the dielectric layer; forming a protecting layer on the sidewall of the opening; the protecting layer comprising a higher carbon concentration than the porous low-K dielectric layer; and forming a first barrier layer over the opening. The protecting layer may comprise an oxygen-containing or nitrogen-containing material.

In accordance with yet another embodiment of the present invention, a method for fabricating a semiconductor structure with a pore-sealing process is provided. The method includes providing a substrate with a porous low-K dielectric layer formed thereon; forming an opening through the dielectric layer; performing a plasma treatment on the sidewall of the opening, the plasma treatment resulting in a carbonated, nitrogenated and/or oxidized portion of the porous low-K dielectric layer along the sidewall of the opening. A barrier layer may be subsequently formed along the sidewalls of the opening and the opening filled with a conductive material.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1e illustrate steps that may be performed to fabricate barrier layers in accordance with a first embodiment of the present invention;

FIGS. 2a-2d illustrate steps that may be performed to fabricate barrier layers in accordance with a second embodiment of the present invention; and

FIG. 3 illustrates an element analysis of a cross-section of a via formed in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed herein are merely illustrative of specific ways to make and use the invention, and do not limit the scope of the invention.

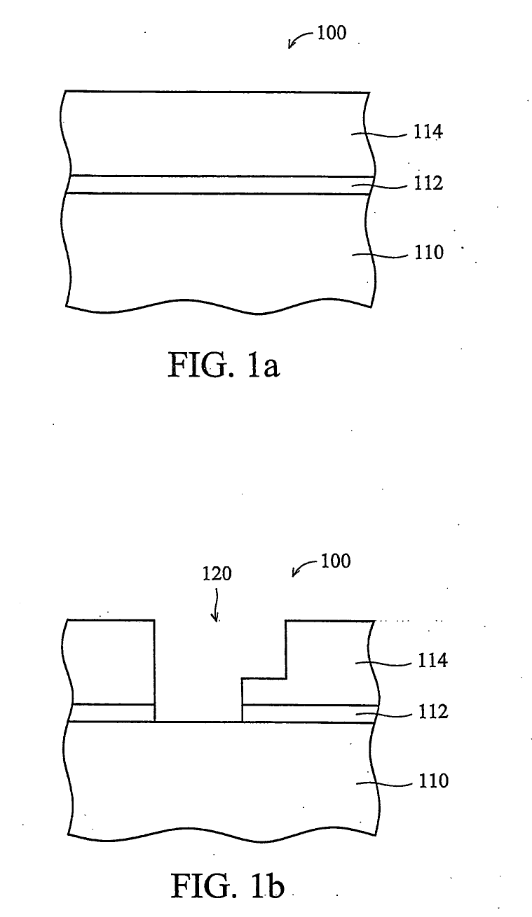

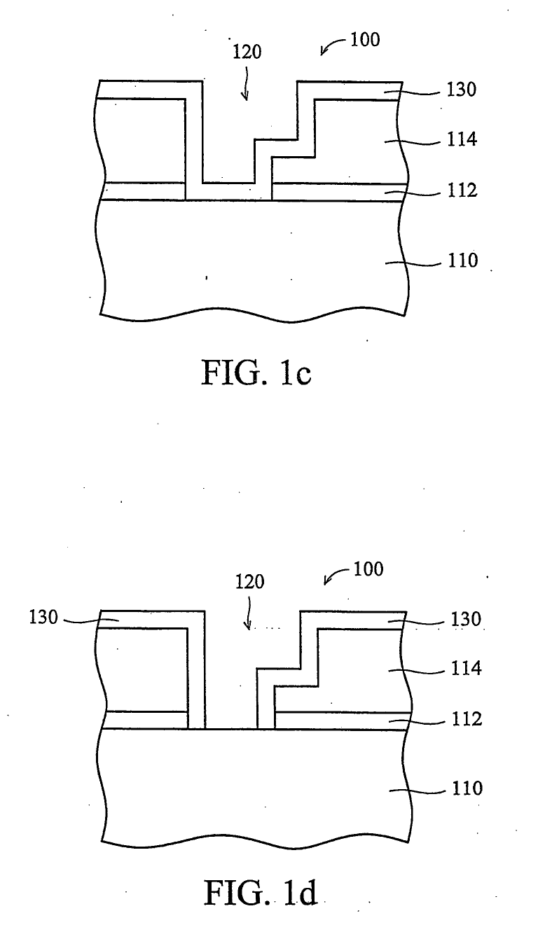

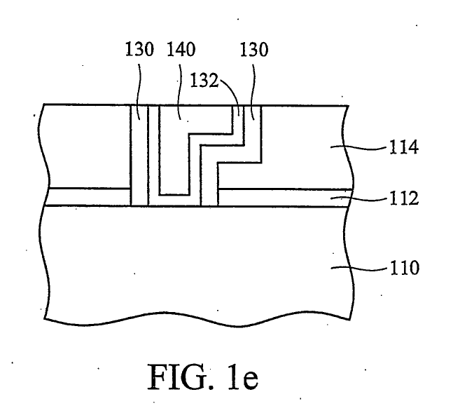

Referring now to FIG. 1a, a substrate 100 is provided having a conductive layer 110, an etch stop layer 112, and an IMD layer 114. Although it is not shown, the substrate 100 may include circuitry and other structures. For example, the substrate 100 may have formed thereon transistors, capacitors, resistors, interconnects and the like. In an embodiment, the conductive layer 110 is a metal layer that is in contact with electrical devices or another metal layer.

The conductive layer 110 may be formed of any conductive material, but an embodiment of the present invention has been found to be particularly useful in applications in which the conductive layer 110 is formed of copper. As discussed above, copper provides good conductivity with low resistance. The etch stop layer 112 provides an etch stop that may be used to selectively etch the IMD layer 114 in a later processing step. In an embodiment, the etch stop layer 112 may be formed of a dielectric material such as a silicon-containing material, a nitrogen-containing material, an oxygen-containing material, a carbon-containing material or the like. The IMD layer 114 is preferably formed of a low-K dielectric material, such as a carbon-containing material, a nitrogen-containing material, an oxygen-containing material, or the like. The carbon-containing material, nitrogen-containing material, or oxygen-containing material of the IMD layer 114 may be a carbon-doped material, a nitrogen-doped material, or an oxygen-doped material. An embodiment of the present invention may be useful when using dielectric materials having a dielectric constant less that about 3.0. Other embodiments of the present invention may be particularly useful when dielectric materials having a dielectric constant less that about 2.75 are used.

It should be noted that the materials selected to form the conductive layer 110, the etch stop layer 112, and the IMD layer 114 should be selected such that a high-etch selectivity exists between the IMD layer 114 and the etch stop layer 112 and between etch stop layer 112 and the conductive layer 110. In this manner, shapes may be formed in the layers as described below. Accordingly, in an embodiment, the IMD layer 114 utilizes materials such as carbon-doped silicon oxide (SiOC) formed by deposition techniques such as CVD, PECVD, Spin-On, LPCVD, or ALD-CVD. In this embodiment, silicon carbide has been found to be a suitable material for the etch stop layer 112 in which a copper damascene structure is being fabricated.

Referring now to FIG. 1b, an opening, e.g., via 120, is formed. It should be noted that a via and a trench are used as an opening for illustrative purposes only. Embodiments of the present invention may be used with other types of openings. It should also be noted that the via 120 is illustrated as a dual-damascene structure for illustrative purposes only and may be formed by one or more process steps (e.g., a single damascene process). The via 120 may be formed by photolithography techniques known in the art. Generally, photolithography involves depositing a photoresist material and then irradiating (exposing) and developing in accordance with a specified pattern to remove a portion of the photoresist material. The remaining photoresist material protects the underlying material from subsequent processing steps, such as etching. The etching process may be a wet or dry, anisotropic or isotropic, etch process, but preferably is an anisotropic dry etch process. After the etching process, the remaining photoresist material may be removed.

In an embodiment in which the IMD layer 114 is formed of FSG, the etch stop layer 112 is formed of silicon nitride, and the conductive layer 110 is formed of copper, the via 120 may be etched with, for example, a solution of CF₄, C₅F₈ or C₄F₈, wherein the etch stop layer 112 acts as an etch stop. Thereafter, the underlying etch stop layer 112 may be etched with, for example, a solution of CF₄, thereby exposing the surface of the conductive layer 110.

It should be noted that a pre-clean process may be performed to remove impurities along the sidewalls of the via 120 and to clean the underlying conductive layer 110. The pre-clean process may be a reactive or a non-reactive pre-clean process. For example, a reactive process may include a plasma process using a hydrogen-containing plasma, and a non-reactive process may include a plasma process using an argon-containing or helium-containing plasma. The pre-clean process may be also a plasma process using a combination of the above gases containing plasma.

FIG. 1c illustrates the substrate 100 of FIG. 1b after a protecting layer 130 has been formed in accordance with an embodiment of the present invention. As discussed above, the IMD layer 114 through which the via 120 is formed typically comprises a porous material, such as a low-K dielectric material. In accordance with an embodiment of the present invention, one or more sealing processes may be performed to partially or completely seal the exposed pores of the IMD layer 114 by simultaneously forming a protecting layer 130 on the surface of the IMD layer 114 with the via 120. By sealing the pores of the IMD layer 114, the surface of the IMD layer 114 with the via 120 is smoother by providing a protecting layer 130 with a more uniform surface upon which subsequent barrier layers may be formed, resulting in a more uniform barrier layer. The process to perform the sealing process and to perform the protecting layer may be a plasma treating and film depositing method, such as a PECVD method or a plasma treatment combined with any depositing method.

In an embodiment, the protecting layer 130 is formed of a dielectric material comprising a silicon-containing material, a carbon-containing material, a nitrogen-containing material, an oxygen-containing material, or the like. Preferably, the protecting layer 130 is formed by a PECVD process to a thickness of about 10 Å to about 500 Å. For example, a protecting layer 130 may be formed of silicon nitride using a PECVD process using silane and N₂O gases.

Referring now to FIG. 1d, the substrate 100 of FIG. 1c is shown after the protecting layer 130 is removed along the bottom of the via 120. As discussed above, the protecting layer 130 is formed of a dielectric material. Therefore, to allow better electrical properties between the conductive plug and the underlying conductive layer, it is preferred that the protecting layer 130 along the bottom of the via be removed. The protecting layer 130 along the bottom of the via 120 may be removed by a wet or dry etch process. It should be noted that a portion of the protecting layer 130 along the bottom of the trench may be removed during this process. However, it is preferred to adjust the etch parameters such that at least a portion of the protecting layer 130 remain along the bottom of the trench to prevent or reduce the diffusion between a conductive plug and the IMD layer 114 along the bottom of the trench.

It should be noted that the surface of the conductive layer 110 may be recessed in the via 120 as a result of removing the first barrier layer 130 along the bottom of the via 120. In a preferred embodiment, the depth of the recess is less than about 800 Å.

FIG. 1e illustrates the substrate 100 after a barrier layer 132 is formed, the via 120 is filled with a conductive plug 140, and the surface planarized in accordance with an embodiment of the present invention. The barrier layer 132 preferably comprises one or more layers of a conductive material that further prevents or reduces diffusion into the IMD layer 114 and provides good adhesive qualities for the conductive plug 140. In an embodiment, the barrier layer 132 may comprise layers of titanium nitride and titanium silicon nitride.

In an embodiment, the conductive plug 140 comprises a copper material formed by depositing a copper seed layer and forming a copper layer via an electro-plating process. The substrate 100 may be planarized by, for example, a chemical-mechanical polishing (CMP) process. Thereafter, standard processes may be used to complete fabrication and packaging of the semiconductor device.

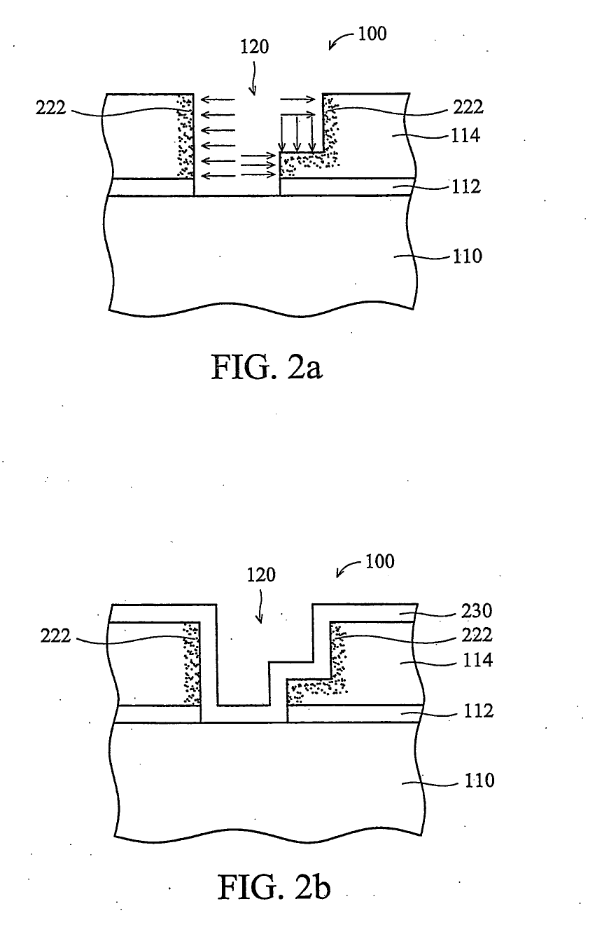

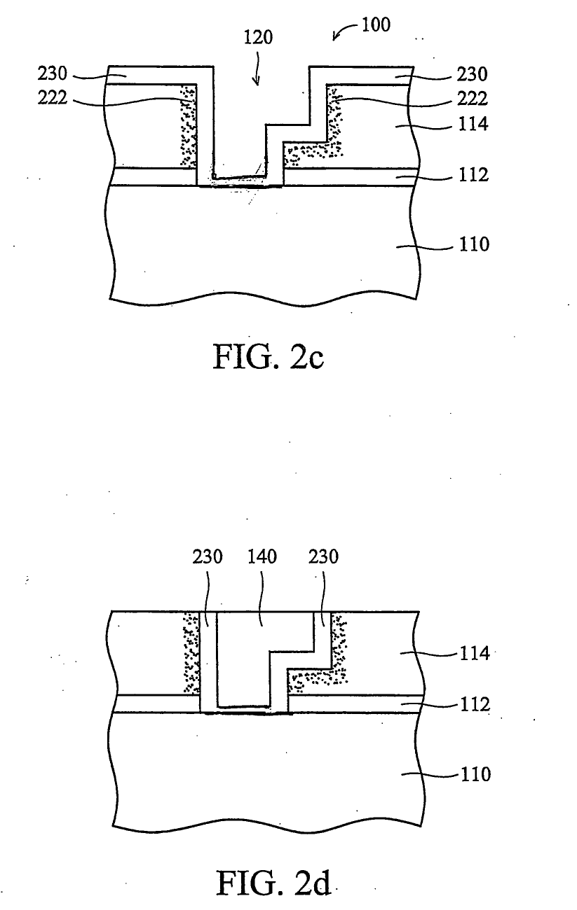

FIGS. 2a-2d illustrate a second embodiment of the present invention. The process illustrated in FIGS. 2a-2d assume the via 120 has been formed in the IMD layer 114 as described above with reference to FIGS. 1a-1b. Accordingly, FIG. 2a illustrates the substrate 100 of FIG. 1b having a pore-sealing process performed, indicated by the directional arrows.

The sealing process may be performed by exposing the substrate 100 to a pore-sealing plasma. In an embodiment, the sealing process is performed by exposing the substrate 100 to a plasma having a gas source containing a gas such as argon, hydrogen, oxygen, nitrogen, helium, or a combination thereof. The plasma treatment will induce a plasma treated portion 222 in the IMD layer 114. The pores in the plasma treated portion 222 will be substantially sealed by the plasma treatment. The plasma treated portion 222 may contain a higher concentration of carbon, nitrogen, and/or oxygen than the bulk portion within the IMD layer 114. The plasma treated portion 222 may also comprise a carbonated, nitrogenated, and/or oxidized portion due the plasma treatment. Optionally, a protecting layer (not shown in FIG. 2a) may be formed along the sidewalls of the opening as discussed above with reference to FIGS. 1a-1e.

The plasma treatment may be performed at a time period of about 10 to about 100 seconds and a temperature of about 0° to about 400° C. with low RF energy of about 200 eV to about 800 eV with high RF energy of about 200 eV to about 800 eV with substrate bias about 0 to about 400 W. Examples of gas sources that may be used for the pore-sealing process include Ar/H₂, Ar/N₂, Ar/He, H₂/He, H₂/N₂, Ar/O₂, O₂/N₂, or the like. Other gases that may be used include an argon-containing gas, a hydrogen-containing gas, a nitrogen-containing gas, a helium-containing gas, an oxygen-containing gas, a combination thereof, or the like.

FIG. 2b illustrates the substrate 100 of FIG. 2a after a first barrier layer 230 has been formed. Because the sealing process described above with reference to FIG. 2a substantially seals the pores of the IMD layer 114, the first barrier layer 230 is formed on a smoother surface. The smoother surface allows the first barrier layer 230 to form a more uniform and continuous barrier layer than previously available. As a result, it has been found that the resulting barrier layer may provide better diffusion properties.

In an embodiment, the first barrier layer 230 may comprise a silicon-containing layer, carbon-containing layer, nitrogen-containing layer, hydrogen-containing layer, or a metal or a metal compound containing layer, such as tantalum, tantalum nitride, titanium, titanium nitride, titanium zirconium, titanium zirconium nitride, tungsten, tungsten nitride, alloys, or combinations thereof. The first barrier layer 230 may be formed by a process such as physical vapor deposition (PVD), chemical vapor deposition (CVD), plasma-enhanced CVD (PECVD), low-pressure CVD (LPCVD), atomic layer deposition (ALD), spin-on deposition, or other suitable methods. In an embodiment, the first barrier layer 230 is tantalum formed by a PVD process. The first barrier layer 130 may comprise multiple layers.

Referring now to FIG. 2c, an optional process may be performed to completely or partially remove the first barrier layer 230 along the bottom of the via 120. FIG. 2c illustrates an embodiment in which the first barrier layer 230 is partially removed. In another embodiment, the first barrier layer 230 may be completely removed, thereby exposing the underlying conductive layer 110. Completely or partially removing the first barrier layer 230 along the bottom of the via 120 may be particularly useful in embodiments in which multiple barrier layers are used to provide diffusion and/or adhesion properties along the sidewalls, but fewer or thinner barrier layers are desired along the bottom to reduce contact resistance. It should also be noted that one or more additional barrier/adhesion barriers may be formed after removing the bottom portion of the first barrier layer 230. The bottom or the first barrier layer 230 may be removed by a dry or wet process.

It should be noted that the surface of the conductive layer 110 may be recessed in the via 120 as a result of removing the first barrier layer 230 along the bottom of the via 120. In an embodiment, the depth of the recess portion is less than about 800 Å.

FIG. 2d illustrates the substrate 100 after the via 120 is filled with a conductive plug 140 and the surface planarized. In an embodiment, the conductive plug 140 comprises a copper material formed by depositing a copper seed layer and forming a copper layer via an electro-plating process. The substrate 100 may be planarized by, for example, a chemical-mechanical polishing (CMP) process. Thereafter, standard processes may be used to complete fabrication and packaging of the semiconductor device.

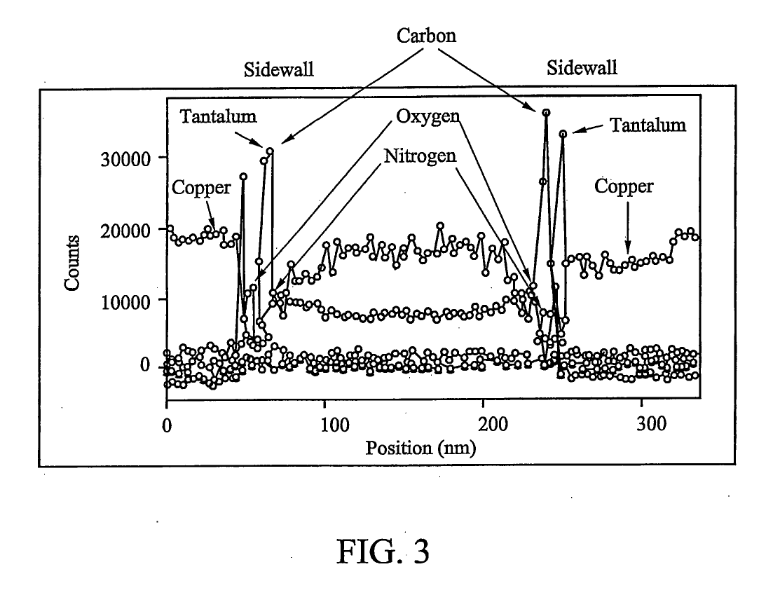

FIG. 3 is a graph illustrating the composition of a cross section taken across a via that was formed in accordance with the process described above. As illustrated in FIG. 3, it has been found that a result of the processes described above is a higher concentration of carbon, oxygen, and nitrogen formed along the sidewalls. As illustrated in FIG. 3, the position indicated as the sidewalls exhibit a higher concentration of nitrogen, oxygen, and carbon than the material of the IMD layer.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor structure comprising:
a low-K dielectric layer on a substrate;
an opening extended through the low-K dielectric layer;
a protecting layer formed on the low-K dielectric layer along sidewalls of the opening with higher carbon concentration than the low-K dielectric layer; and
a conductive material filling in the opening.

2. The semiconductor structure of claim 1, further comprising one or more barrier layers on the protecting layer.

3. The semiconductor structure of claim 1, wherein the protecting layer comprises an oxygen-containing material.

4. The semiconductor structure of claim 3, wherein the protecting layer has a higher concentration of oxygen than the low-K dielectric layer.

5. The semiconductor structure of claim 1, wherein the protecting layer comprises a nitrogen-containing material.

6. The semiconductor structure of claim 5, wherein the protecting layer has a higher concentration of nitrogen than the low-K dielectric layer.

7. The semiconductor structure of claim 1, wherein the protecting layer is between about 10 Å and about 500 Å in thickness.

8. The semiconductor structure of claim 1, wherein the low-K dielectric layer has a dielectric constant less than about 3.0.

9. The semiconductor structure of claim 1, wherein the low-K dielectric layer has a dielectric constant less than about 2.75.

10. The semiconductor structure of claim 1, wherein the opening is a dual damascene opening.

11. The semiconductor structure of claim 10, wherein the substrate further comprises a conductive layer underlying the dual damascene opening with a recess portion less than 800 angstroms.

12. A semiconductor structure comprising:
a low-K dielectric layer on a substrate;
an opening extended through the low-K dielectric layer, the low-K dielectric layer having a plasma treated portion on a sidewall of the opening;
one or more barrier layers formed along the sidewalls of the opening; and
a conductive material filling the opening.

13. The semiconductor structure of claim 12, wherein the plasma treated portion bas a thickness along the sidewall of the opening between about 10 Å and about 500 Å in thickness.

14. The semiconductor structure of claim 12, wherein the low-K dielectric layer has a dielectric constant less than about 3.0.

15. The semiconductor structure of claim 12, wherein the low-K dielectric layer has a dielectric constant less than about 2.75.

16. The semiconductor structure of claim 12, wherein the plasma treated portion has a higher concentration of carbon than the low-K dielectric layer.

17. The semiconductor structure of claim 12, wherein the sidewalls of the plasma treated portion have a higher concentration of nitrogen than the low-K dielectric layer.

18. The semiconductor structure of claim 12, wherein the sidewalls of the plasma treated portion have a higher concentration of oxygen than the low-K dielectric layer.

19. The semiconductor structure of claim 12, wherein the opening is a dual damascene opening with a via and a trench.

20. The semiconductor structure of claim 19, wherein the low-K dielectric layer further comprises a plasma treated portion on a bottom of the trench.

21.-37. (canceled)
